(19) United States
(12) Patent Application Publication
(10) Pub. No.: US 2020/0196493 A1
(43) Pub. Date: Jun. 18, 2020

(54) SHIELD COVER AND ASSEMBLY BODY

(71) Applicant: Sumitomo Wiring Systems, Ltd., Yokkaichi (JP)

(72) Inventor: Takeru Miyamoto, Yokkaichi (JP)

(21) Appl. No.: 16/699,969

(22) Filed: Dec. 2, 2019

(30) Foreign Application Priority Data
Dec. 14, 2018 (JP) 2018-234257

(51) Int. Cl. H05K 9/00

(52) U.S. Cl. CPC H05K 9/002

(57) ABSTRACT

A shield cover includes a shield cover body, a mounting plate and a rib. The shield cover body has a container shape and covers an object to be shielded. The mounting plate protrudes from the shield cover body and includes a bolt hole. A bolt for assembling the shield cover with an assembly destination is inserted into the bolt hole in a fastening direction. The rib rises from the mounting plate in the fastening direction.

### BACKGROUND

### Field of the Invention

The invention relates to a shield cover and an assembly body with the shield cover.

### Related Art

A shield cover with a shield cover body and a mounting plate is known. This shield cover is assembled with an assembly destination by a bolt inserted through a bolt hole of the mounting plate. Consideration has been given to incorporating a rib into the mounting plate to improve the strength of the shield cover.

For example, Japanese Unexamined Patent Publication No. 2017-84959 discloses a shield cover with a cover body, a right mounting plate and a left mounting plate. The cover body is formed into a substantially cubic shape and covers an object to be shielded. The right and left mounting plates protrude from the cover body, and bolt insertion holes penetrate through the right and left mounting plates. The shield cover is mounted on a terminal block by bolts. Japanese Unexamined Patent Publication No. 2017-84959 proposes a rib to reinforce a part not sandwiched by the bolt and a bracket.

The shield cover described in Japanese Unexamined Patent Publication No. 2017-84959 has a problem in that the rib interferes with a bolt tightening tool when mounting the shield cover on the terminal block by the bolts and an operation of mounting the shield cover is not easy. Thus, improved strength of the shield cover and an easy mounting of the shield cover cannot be combined.

The invention was developed in view of this problem. An object of the invention is to provide a shield cover with improved strength and an easy operation of assembling the shield cover.

### SUMMARY

The invention relates to a shield cover that includes a shield cover body, a mounting plate and a rib. The shield cover body has a container shape and covers an object to be shielded. The mounting plate protrudes from the shield cover body and includes a bolt hole. A bolt for assembling the shield cover with an assembly destination is inserted into the bolt hole in a fastening direction. The rib rises from the mounting plate in the fastening direction.

The invention also relates to an assembly body including the shield cover, the assembly destination, and the bolt.

According to the invention, the rib improves the strength of the shield cover. Further, the rib rises in the fastening direction and therefore does not interfere with a bolt tightening tool. Therefore, an operation of assembling the shield cover with the assembly destination is facilitated. Accordingly, the invention improves the strength of the shield cover and facilitates the operation of assembling the shield cover with the assembly destination.

### BRIEF DESCRIPTION OF DRAWINGS

FIG. 1 is a perspective view schematically showing a state where a shield cover of an embodiment is assembled with an assembly destination.

FIG. 2 is a perspective view schematically showing the state where the shield cover of the embodiment is assembled with the assembly destination.

FIG. 3 is a bottom view schematically showing the shield cover of the embodiment.

### DETAILED DESCRIPTION

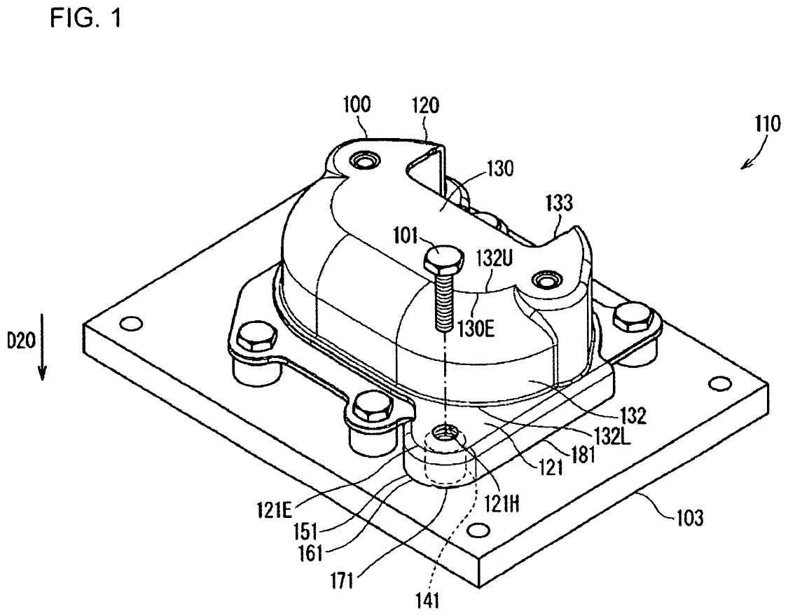

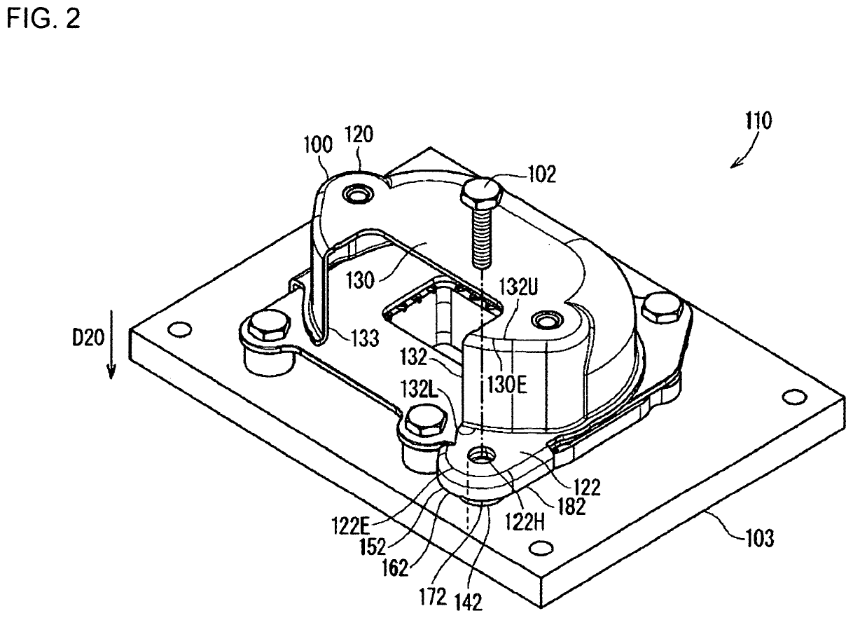

The shield cover 100 of this embodiment is assembled with the assembly destination 103 by a first bolt 101 and a second bolt 102, as shown in FIGS. 1 and 2. The shield cover 100, the first bolt 101, the second bolt 102 and the assembly destination 103 form an assembly body 110. The assembly destination 103 includes an unillustrated object to be shielded. The object to be shielded includes an electrical terminal, an electrical wiring and the like in this embodiment, e.g. an electrical terminal, an electric wiring and the like mounted in an automotive vehicle to transfer drive power of the automotive vehicle. The shield cover 100 is made mainly of metal or alloy and shields the object to be shielded.

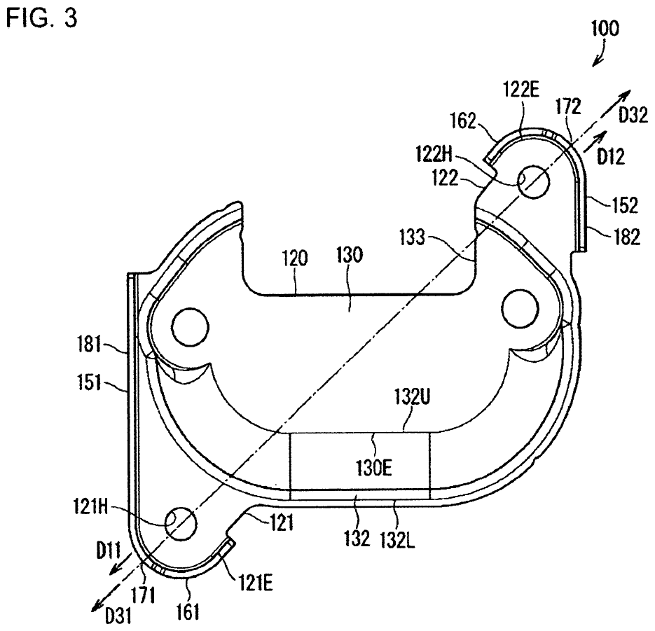

As shown in FIGS. 1, 2 and 3, the shield cover 100 includes a shield cover body 120, a first mounting plate 121 and a second mounting plate 122. The shield cover 100 is fabricated by drawing or the like.

The shield cover 100 has a container shape and covers the object to be shielded. The shield cover 100 includes an upper wall 130 and a side wall 132. The side wall 132 is at a position closer to the assembly destination 103 than a position where the upper wall 130 is arranged. An upper end part 132U of the side wall 132 is connected to an edge 130E of the upper wall 130. The shield cover body 120 includes an opening 133 that extends over the upper wall 130 and the side wall 132. An electrical wiring, an electrical connector and the like to be connected to the object to be shielded are passed through the opening 133.

The first and second mounting plates 121, 122 protrude from a lower end part 132L of the side wall 132 of the shield cover body 120. More particularly, the first and second mounting plates 121, 122 protrude respectively in opposite first and second protruding directions D11 and D12.

The first and second mounting plates 121, 122 respectively include a first bolt hole 121H and a second bolt hole 122H. The assembly destination 103 includes a first boss 141 and a second boss 142, and each of the first and second bosses 141, 142 has a boss hole. The first and second bolts 101, 102 are inserted respectively into the first and second bolt holes 121H, 122H in a fastening direction D20, and are screwed respectively into the bolt holes of the first and second bosses 141, 142. In this way, the shield cover 100 is assembled with the assembly destination 103. The fastening direction D20 of the first bolt 101 is an advancing direction of the first bolt 101 when the first bolt 101 is screwed into the bolt hole of the first boss 141. The insertion of the first bolt 101 into the first bolt hole 121H in the fastening direction D20 means the passage of a shaft of the first bolt 101 through the first bolt hole 121H with the first mounting plate 121 arranged farther in the fastening direction D20 than a head of the first bolt 101. The same also applies to the second bolt 102.

The shield cover 100 further includes a first rib 151 and a second rib 152. The first and second ribs 151, 152 respectively rise in the fastening direction D20 from the first and second mounting plates 121, 122. The first and second ribs 151, 152 rise from an edge part 121E of the first mounting plate 121 and an edge part 122E of the second mounting plate 122.

The first and second ribs 151, 152 improve the strength of the shield cover 100. Further, the first and second ribs 151, 152 rise in the fastening direction D20 and therefore do not interfere with a bolt tightening tool and an operation of assembling the shield cover 100 is facilitated. Accordingly, a strength improvement of the shield cover 100 and an easy assembling of the shield cover 100 with the assembly destination 10 can be combined.

The first and second ribs 151, 152 respectively include a first circumferentially extending part 161 and a second circumferentially extending part 162. The first and second circumferentially extending parts 161, 162 extend in circumferential directions about center axes of the first and second bolt holes 121H, 122H. Additionally, the first and second circumferentially extending parts 161, 162 are arranged along the outer peripheral surfaces of the first and second bosses 141, 142 when the shield cover 100 is assembled with the assembly destination 102.

If an attempt is made to move the shield cover 100 horizontally, the first circumferentially extending part 161 butts against the first boss 141 or the second circumferentially extending part 162 butts against the second boss 142. Thus, the first and second circumferentially extending parts 161, 162 function as a positioning structure for restricting a horizontal movement of the shield cover 100 and determining a horizontal position of the shield cover 100.

The first rib 151 includes a part 171 located in a first direction D31 when viewed from the first bolt hole 121H, and the second rib 152 includes a part 172 located in a second direction D32 when viewed from the second bolt hole 122H. The second direction D32 is opposite to the first direction D31. Further, the shield cover body 120 is arranged between the first and second mounting plates 121, 122 in a plan view viewed in a thickness direction of the first and second mounting plates 121, 122. In this way, horizontal movements of the shield cover 100 in the first and second directions D31, D32 can be suppressed effectively.

The first and second ribs 151, 152 further respectively include an extended part 181 and an extended part 182. The extended parts 181, 182 are respectively continuous from the first and second circumferentially extending parts 161, 162 and extended from the first and second circumferentially extending parts 161, 162 in directions away from the first and second bolt holes 121H, 122H. In this way, the strength of the shield cover 100 is improved further.

### LIST OF REFERENCE SIGNS

100 shield cover
101 first bolt
102 second bolt
103 assembly destination
110 assembly body
120 shield cover body
121 first mounting plate
122 second mounting plate
141 first boss
142 second boss
151 first rib
152 second rib

What is claimed is:

1. A shield cover (100), comprising:
a shield cover body (120) having a container shape and configured to cover an object to be shielded;
a mounting plate (121) protruding from the shield cover body (120) and including a bolt hole, a bolt (101) for assembling the shield cover (100) with an assembly destination (103) being inserted into the bolt hole (121H) in a fastening direction (D20); and
a rib (151) rising from the mounting plate (121) in the fastening direction (D20).

2. The shield cover (100) of claim 1, wherein the rib (151) includes a circumferentially extending part (161) extending in a circumferential direction about a center axis of the bolt hole (121H).

3. The shield cover (100) of claim 2, wherein the rib (151) further includes an extended part (181) continuous from the circumferentially extending part (161) and extended from the circumferentially extending part (161) in a direction away from the bolt hole (121H).

4. The shield cover (100) of claim 3, wherein:
the mounting plate (121) is a first mounting plate (121);
the bolt hole (121H) is a first bolt hole (121H);
the rib (151) is a first rib (151);
the bolt (101) is a first bolt (101); and
the shield cover (100) further comprises:
a second mounting plate (122) protruding from the shield cover body (120) and including a second bolt hole (122H), a second bolt (102) for assembling the shield cover (100) with the assembly destination (103) being inserted into the second bolt hole (122H) in the fastening direction; and
a second rib (152) rising from the second mounting plate (122) in the fastening direction (D20).

5. The shield cover of claim 4, wherein:
the first rib (151) includes a part located in a first direction when viewed from the first bolt hole (121H);
the second rib (152) includes a part located in a second direction opposite to the first direction when viewed from the second bolt hole (122H); and
the shield cover body (120) is arranged between the first mounting plate (121) and the second mounting plate (122) in a plan view viewed in a thickness direction of the first mounting plate (121) and the second mounting plate (122).

6. An assembly body, comprising:
the shield cover (100) of claim 1;
an assembly destination (103); and
a bolt (101).

7. The assembly body of claim 6, wherein:
the assembly destination (103) includes a boss (141) having a bolt hole and an outer peripheral surface, the bolt (101) being screwed into the bolt hole (121H); and
the rib (151) includes a part to be arranged along the outer peripheral surface.
